(19) United States
(12) Patent Application Publication
(10) Pub. No.: US 2007/0252607 A1
(43) Pub. Date: Nov. 1, 2007

(54) Method of manufacturing circuit module, collective board for circuit module, and circuit module manufactured by the method

(75) Inventor: Hidekatsu Muroi, Fukushima-ken (JP)

Correspondence Address: BEYER WEAVER LLP, P.O. BOX 70250, OAKLAND, CA, 94612-0250, US

(73) Assignee: ALPS ELECTRIC CO., LTD.

(21) Appl. No.: 11/789,162

(22) Filed: Apr. 23, 2007

(30) Foreign Application Priority Data
May 1, 2006 (JP) 2006-127778

(51) Int. Cl. G01R 31/02

(52) U.S. Cl. 324/754

(57) ABSTRACT

A method of manufacturing a circuit module having a low price and good productivity, a collective board for the circuit module, and a circuit module manufactured by the method are provided. In the method of manufacturing the circuit module of the invention, when performing a burn-in test, a collective board 1 having a circuit board 2 can be used as a test board. Accordingly, since it is not necessary to have an additional test board, it is possible to obtain a low price product. In addition, since a test is performed in a state where the bare chip 8 is attached (e.g., soldering) to the circuit board 2, the number of the process of the bare chip 8. Accordingly, it is possible to obtain good productivity.

### BACKGROUND OF THE INVENTION

1. Field of the Invention

The present invention relates to a method of manufacturing a circuit module in which a bare chip is mounted used for a local-area wireless device and the like, a collective board for a circuit module, and the circuit module manufactured by the method.

2. Description of the Related Art

A related manufacturing method of a circuit module and the circuit module manufactured by the method of manufacturing the circuit module will be described with reference to the drawings. FIG. 7 is a top plan view illustrating a circuit board about the known circuit module. FIG. 8 is a top plan view illustrating the known circuit module and a method of manufacturing the circuit module. FIG. 9 is a schematic diagram illustrating a burn-in test substrate of a bare chip about a method of manufacturing the known circuit module. FIG. 10 is an explanation view illustrating a method of manufacturing a burn-in test of the bare chip about the method of manufacturing the known circuit module.

Next, the method of manufacturing the known circuit module will be described with reference to the FIGS. 7 to 10. Firstly, as shown in FIG. 7, a separately divided substrate 50 is provided. The substrate 50 includes a plurality of first land portions 51a, a plurality of second land portions 51b, and a module 51 having a circuit pattern 51c connected to the first land portion 51a and the second land portion 51b.

Next, as shown in FIG. 8, in the first land portion 51a connected to a bare chip 52 selected by a following burn-in test (aging test), a circuit module having the second land portion 51b connected to an electronic part 53 having various chip parts other than the bare chip 52, as shown in FIG. 8, may be formed.

In addition, the bare chip 52 which is used for the method of manufacturing the known circuit module and the circuit module is electrified by the burn-in test substrate shown in FIGS. 9 and 10 so as to perform the burn-in test (aging test). Accordingly, a product which has a good quality and passes the test has been used so far.

In addition, the burn-in test (aging test) of the bare chip 52 is performed by a semiconductor manufacturing maker. The semiconductor manufacturing maker sells the product which has a good quality and passes the burn-in test. A bare chip using maker who manufactures the circuit module buys the bare chip 52 having a good quality and mounts the bare chip 52 on the circuit board 50.

Next, a burn-in test substrate of a bare chip about the method of manufacturing the known circuit module and the method of the same will be described with reference to FIGS. 9 and 10. The burn-in test substrate 55 includes a test substrate 56, a conductive pattern 57 having a plurality of electrode pads 57a which is disposed in the test substrate 56 and test a plurality of bare chips 52, and an insulation layer 58 provided on the test substrate 56 in a state where an electrode pad 57a is exposed. In addition, the bare chip 52 is pressed by a pressing member 59.

In addition, the method of the burn-in test of the bare chip will be described hereinafter. Firstly, a main body portion 52a of the bare chip 52 is disposed on the insulation layer 58. A plurality of electrodes 52b disposed in a lower surface of the main body portion 52a of the bare chip 52 is connected to the electrode pads 57a, respectively, and the pressing member 59 is disposed on the main body portion 52a. Accordingly, the electrodes 52b are pressed into the electrode pads 57a by the pressing member 59, respectively.

Next, the burn-in test substrate 55 disposing the plurality of bare chips 52, for example, is transported to a heating furnace (not shown) having a high temperature at 125° C., and the bare chip 52 performs the burn-in test (aging test) during 24 hours through the conductive pattern 57 in a state where the electrification is maintained. Accordingly, reliability test of the bare chip 52 will be performed (e.g., refer to JP-A-6-340995).

As a result, by the burn-in test (aging test), the bare chips 52 measures electric characteristics of a predetermined item so as to detect normal goods and inferior goods. Accordingly, the inferior goods are removed, and only the products having a good quality will be manufactured to a market after passing an electrical examination process.

In addition, the bare chip 52 performing the burn-in test (aging test) is referred to as KGD type (Known Good Die) and performs reliability test which is performed in a packaged semiconductor parts by an insulation resin.

However, in the method of manufacturing the known circuit module and the circuit module manufactured by the method, the bare chip 52 performs the burn-in test (aging test) by the burn-in test substrate 55 having a test substrate 56 differently from the circuit board 50. Accordingly, the bare chip 52 may be an expensive. Since the maker using the bare chip needs to buy the bare chip 52 having a good quality and mount the bare chip 52 on the circuit board 50, productivity may be lowered.

### SUMMARY OF THE INVENTION

The present invention solves the above-mentioned problems. An object of the invention is to provide a method of manufacturing a circuit module having a low price and good productivity, a collective board for the circuit module, and a circuit module manufactured by the method.

According to an aspect of the invention, a method of manufacturing a circuit module including a plurality of circuit boards having circuit patterns for forming a plurality of circuit modules and a collective board having extensions connected between the plurality of circuit boards to each other, wherein the circuit board includes a plurality of extending patterns which are connected to the circuit patterns, which include a plurality of first land portions for connection to a bare chip and a plurality of second land portions for connection to an electronic part other than the bare chip, and which extend to boundary positions between the circuit boards and the extensions in a state where the plurality of extending patterns are connected to the first land portions, and the extensions include a plurality of extracting patterns connected to the extending patterns. The method includes a first bonding process of connecting the bare chip to the first land portions, a burn-in test process of electrifying the bare chip using the extending patterns and the extracting patterns at a high temperature so as to determine goodness and badness of the bare chip connected to each circuit boards, and a second bonding process of bonding the electronic part to the second land portions of the circuit boards having the bare chip with goodness after performing the burn-in test process.

Accordingly, since in the invention, the collective board having the circuit board can be used as a test board. Accordingly, since it is not necessary to have an additional test board, it is possible to obtain a low price product. In addition, since a test is performed in a state where the bare chip is attached to the circuit board, the number of the process of the bare chip is decreased. Accordingly, it is possible to obtain good productivity and confirm reliability of the bonding state between the bare chip and the first land portion.

In addition, in the invention, a cutting process of cutting the collective board in the boundary positions is performed after performing the second bonding process to the collective board so as to obtain the individual circuit boards.

In the invention, the first connection process attaching the bare chips and the second connection process attaching the electronic parts are continuously performed. Accordingly, it is possible to obtain good productivity.

In addition, in the invention, a cutting process of cutting the collective board of the boundary positions so as to obtain the individual circuit boards is performed, and then the second bonding process is performed after performing the burn-in test process.

In the invention, the circuit board is relatively large and does not make a mounting device of the electronic parts large when various electronic parts are used. Accordingly, it is possible to decrease the mounting device in size.

According to another aspect of the invention, a collective board for a circuit module includes a plurality of circuit boards having a circuit pattern for forming a circuit module, and extensions connected between the circuit boards. The circuit board includes a plurality of extending patterns which are connected to the circuit patterns, which include a plurality of first land portions for connection to a bare chip and a plurality of second land portions for connection to an electronic part other than the bare chip, and which extend to boundary positions between the circuit boards and the extensions in a state where the plurality of extending patterns are connected to the first land portions, and the extensions include a plurality of extracting patterns connected to the extending patterns.

In the invention, the extracting pattern so as to perform the burn-in test is formed in the extension. Accordingly, the collective board may be decreased in size and low-price products may be obtained.

In addition, in the invention, the extensions include a first connection portion disposed between the adjacent circuit boards and a second connection portion disposed in an outer peripheral portion thereof, and the extracting patterns are provided in the first and second connection portions.

In the invention, by the first and the second connection, a formation area is increased. Accordingly, various extracting patterns may be easily formed.

In addition, in the invention, a plurality of burn-in test electrodes are provided in an end portion the extracting pattern. The plurality of burn-in test electrodes are concentrated on the second connection portion disposed in one side of an outer peripheral portion.

In the invention, since the burn-in test electrodes are concentrated on the second connection portion, the burn-in test electrodes are easily electrified.

In addition, in the invention, a plurality of burn-in test electrodes are provided in end portions of the extracting patterns, convex portions protruding outward are provided in the second connection portions disposed in one side of the outer peripheral portion, and the plurality of burn-in test electrodes are concentrated on the convex portions.

In the invention, the burn-in test electrodes are concentrated on the convex portion. Accordingly, the burn-in test electrodes are easily electrified.

According to a further aspect of the invention, the invention includes a circuit board having a circuit pattern, a bare chip mounted on the circuit board, and an electronic part other than the bare chip mounted on the circuit board, in which the circuit pattern includes a plurality of first land portions, a plurality of second land portions so as to connect the electronic part other than the bare chip, and a pattern connected to the first land portions and the second land portions, and in the circuit board, a plurality of extending patterns extending to an end portion of the circuit board in a state where the plurality of extending patterns are connected to the first land portion.

In the invention, by a plurality of extending patterns which are extended to an end portion of the circuit board connected to the first land portion, the bare chip may perform the burn-in test in a state where the bare chip is attached to the circuit board. A collective board having a plurality of circuit boards may be used. In addition, reliability of the bonding state between the bare chip and the first land portion may be confirmed.

In addition, in the invention, the end portions of the extending patterns are disposed in two different sides of the circuit boards.

In the invention, it becomes easy to wire the extending pattern from the first land portion. Accordingly, it is possible to attain easy wiring of the circuit pattern.

In the invention, since the collective board having the circuit board can be used as the test substrate when performing the burn-in test, an additional test substrate may not be needed. Accordingly, low price products may be obtained. In addition, since the test is performed in a state where the bare chip is attached on the circuit board, the process of the bare chip may be decreased. Accordingly, product having good productivity may be obtained and reliability of the bonding between the bare chip and the first land portion may be confirmed.

### BRIEF DESCRIPTION OF THE DRAWINGS

FIG. 1 is a schematic top plan view illustrating a method of manufacturing a circuit module and a collective board according to an invention.

FIG. 2 is an enlarged plan view illustrating the method of manufacturing the circuit module and a main portion of the collective board according to the invention.

FIG. 3 is an enlarged plan view illustrating the method of manufacturing the circuit module and the main portion in a state where a bare chip is attached on the collective board according to the invention.

FIG. 4 is an enlarged cross-sectional view illustrating the method of manufacturing the circuit module and the main portion in a state where a bare chip is attached on the collective board according to the invention.

FIG. 5 is an enlarged cross-sectional view illustrating the method of manufacturing the circuit module and the main portion in a state where electronic parts are attached on the collective board according to the invention.

FIG. 6 is a top plan view illustrating the circuit module according to the invention.

FIG. 7 is a top plan view illustrating a circuit board about the known circuit module.

FIG. 8 is a top plan view illustrating the known circuit module and a method of manufacturing the circuit module.

FIG. 9 is a schematic diagram illustrating a burn-in test substrate of a bare chip about a method of manufacturing the known circuit module.

FIG. 10 is an explanation view illustrating a method of manufacturing a burn-in test of the bare chip about the method of manufacturing the known circuit module.

### DESCRIPTION OF THE PREFERRED EMBODIMENTS

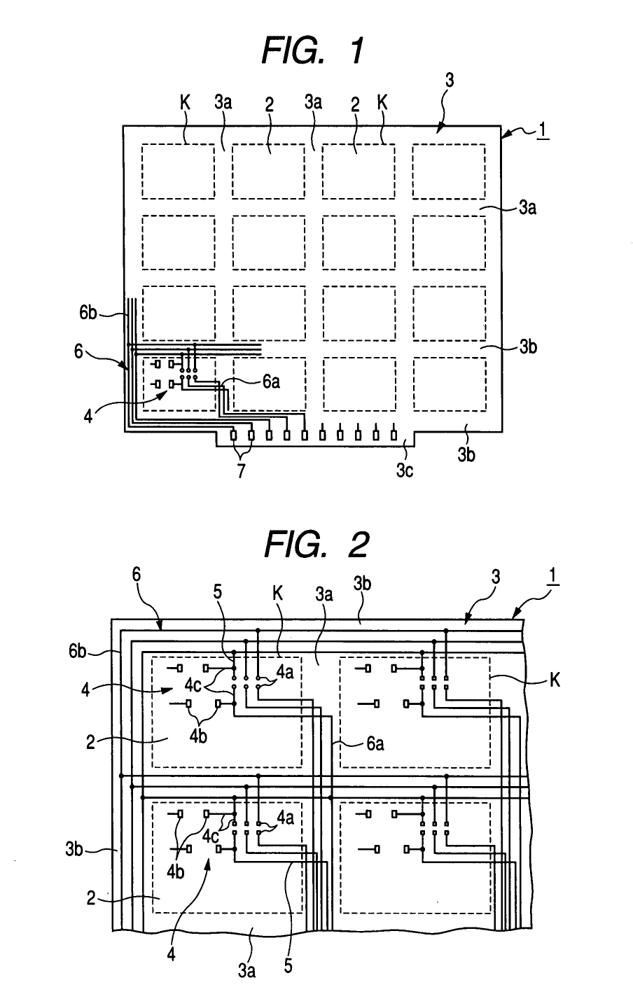

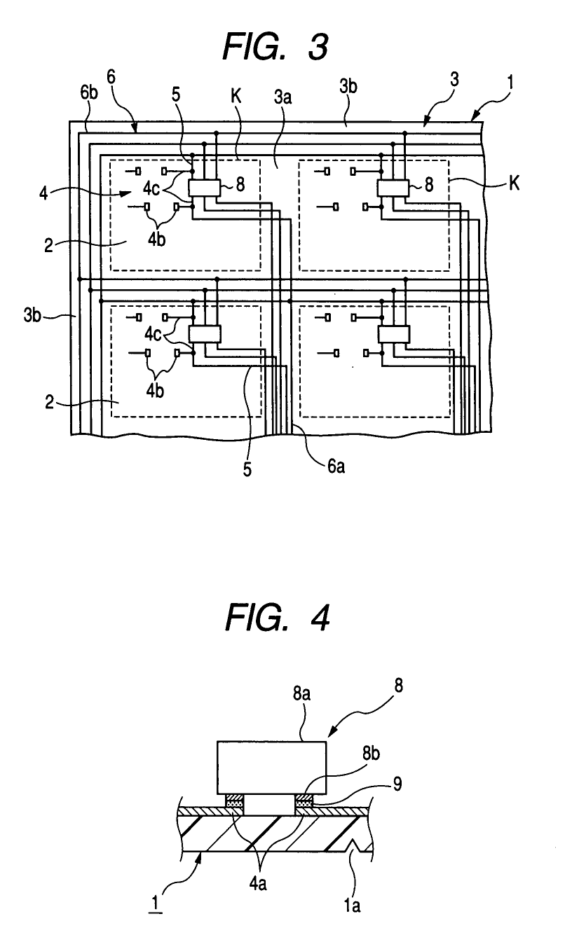

An embodiment will be described with reference to the accompanying drawings according to the present invention. FIG. 1 is a schematic top plan view illustrating a method of manufacturing a circuit module and a collective board according to an invention. FIG. 2 is an enlarged plan view illustrating the method of manufacturing the circuit module and a main portion of the collective board according to the invention. FIG. 3 is an enlarged plan view illustrating the method of manufacturing the circuit module and the main portion in a state where a bare chip is attached on the collective board according to the invention.

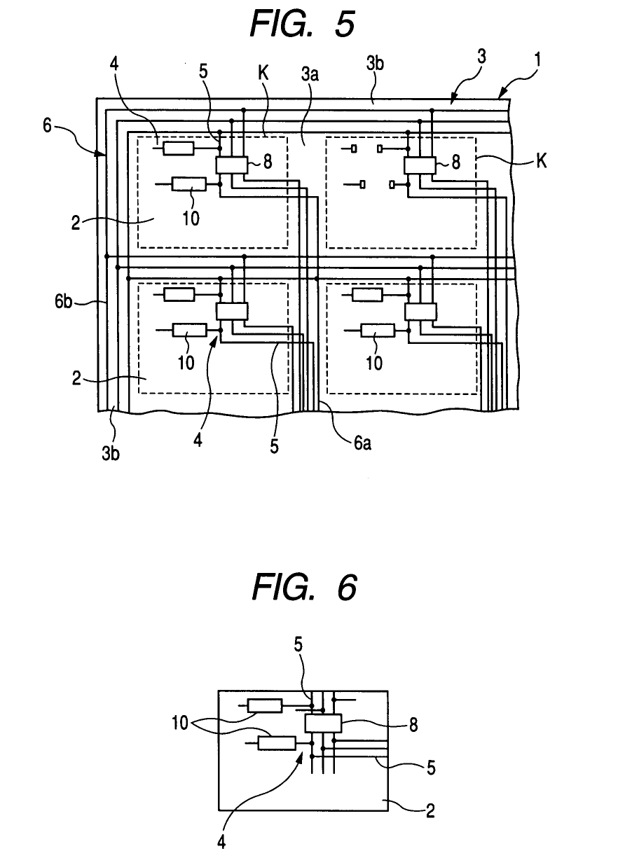

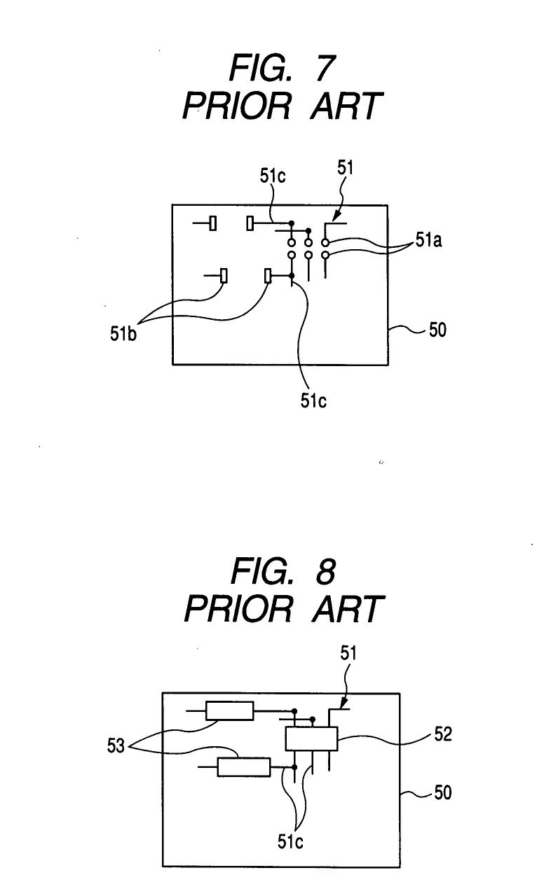

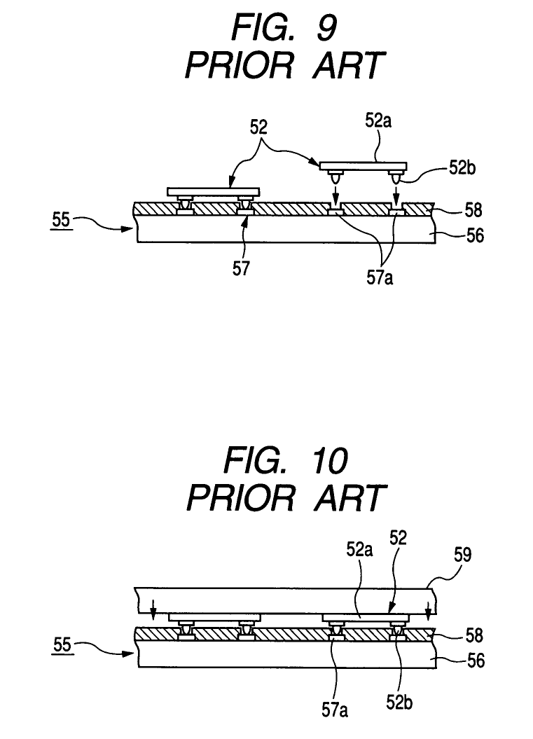

In addition, FIG. 4 is an enlarged cross-sectional view illustrating the method of manufacturing the circuit module and the main portion in a state where a bare chip is attached on the collective board according to the invention. FIG. 5 is an enlarged cross-sectional view illustrating the method of manufacturing the circuit module and the main portion in a state where electronic parts are attached on the collective board according to the invention. FIG. 6 is a plan view illustrating the circuit module according to the invention.

Next, a method of manufacturing the circuit module, a collective board for the circuit module, and a circuit module manufactured by the method of manufacturing the circuit module will be described with reference to FIGS. 1 to 6 according to the invention. Firstly, a collective board 1 so as to form the circuit module is formed of ceramic material having a rectangular shape, as shown in FIGS. 1 and 2, and includes a circuit board 2 (portion with a dotted line) disposed in a predetermined gap in a state where the circuit board 2 is arranged and an extension 3 connected between the circuit board 2. As shown in FIG. 4, a cutting inducing portion 1a which is formed of an extended groove along the circuit board 2 (shown with a dotted line) is provided in an opposite surface of the collective board 1.

The extension 3 includes a first connection portion 3a connected to a gap between the circuit boards 2 opposite to each other, a second connection portion 3b disposed in an outer peripheral portion, and a convex portion 3c protruding outwardly from the second connection portion 3b disposed in one side of the outer peripheral portion.

The circuit board 2 includes a circuit pattern 4 and an extension pattern 5. The circuit pattern 4 includes a plurality of first land portions 4a, a plurality of second land portions 4b, and a pattern 4c connected to the first land portion 4a and the second land portion 4b. An extension pattern 5 is sorted out to different two sides of the circuit board 2 in a state where the extension pattern 5 is connected to the first land portion 4a. The extension pattern 5 extends to a boundary position K of the circuit board 2 and the extension 3.

In addition, the extension 3 includes a plurality of extracting patterns 6. For example, the extracting patterns 6, as shown in FIG. 2, include a first pattern portion 6a disposed in the first connection 3a and a second pattern portion 6b disposed in the second connection portion 3b. The extracting pattern 6 is connected to the extracting pattern 5, respectively. The extracting pattern 6 is drawn by the first pattern portion 6a and the second pattern portion 6b in a state where the extracting pattern 6 is sorted out from the first land portion 4a (two side of the circuit board 2).

In addition, the convex portion 3c of the extension 3 includes a burn-in test electrode 7 arranged in a line. The burn-in test electrode 7 is connected to the extracting pattern 6 and the collective board for the circuit module is formed according to the invention.

The extracting pattern 6 includes a power line, a ground line, a signal input line, and a signal output line. However, the signal input line is extracted from the bare chip 8, the power line, the ground line, and the signal input line are commonly used about the bare chip 8, respectively. In addition, the convex portion 3c is removed and the burn-in test electrode 7 may be concentrated on the second connection portion 3b disposed on one side of an outer peripheral.

Next, a method of manufacturing a circuit module will be described according to the invention. Firstly, as shown in FIGS. 3 and 4, in the first land portion 4a disposed in the respective circuit board 2, a first bonding process in which an electrode 8b disposed in a lower surface of a main body portion 8a of the bare chip 8 is bonded is performed.

Next, the collective board 1 mounting the plurality of bare chips 8, for example, is transported to a heating furnace (not shown) having a high temperature at 125° C., and the bare chip 8 performs the burn-in test during 24 hours through the extracting pattern 6, the extending pattern 5, and the circuit pattern 4 from the burn-in test electrode 7 in a state where the electrification is maintained. Accordingly, reliability test of the bare chip 8 may be performed.

As a result, the respective bare chip 8 measures electrical characteristics of a predetermined item and a disconnection of an inside of the wiring item on the basis of the test process of the burn-in test (aging test). Accordingly, it is possible to distinguish good products and bad products and confirm reliability of the bonding state of the connection member 9 between the bare chip 8 and the first land portion 4a.

In addition, the bare chip 8 performing the burn-in test (aging test) is referred to as a KGD type (Known Good Die) and performs reliability test which is performed in a packaged semiconductor parts by an insulation resin.

In addition, the bare chip 8 for the burn-in test (aging test) uses a KTD type (Known Tested Die) or PD type (Probed Die), which are available at a market.

In addition, in the KTD type, the burn-in test (aging test) is not performed and electric characteristics test of a predetermined item which is the same as semiconductor parts packaged by an insulating layer is performed. In addition, the PD type does not perform the burn-in test (aging test) and electric characteristics test of a part of a predetermined item which is the same as the semiconductor parts packaged by the insulating layer is performed.

Accordingly, by performing the burn-in test (aging test) for the bare chip of the KTD type or the a PD type, it is possible to raise a grade of the bare chip 8 and a value-added.

Next, after performing the test process by the burn-in test (aging test), an electronic part 10 including a filter, a coil, a resistor, a capacitor other than the bare chip 8 is connected to the second land portion 4b on the circuit board 2 in which the circuit board 1 determine the bare chip 8 to have a good quality. A desirable electronic circuit is formed on the respective circuit board 2 with the second bonding process.

In addition, after performing the second bonding process, in a position of the cutting inducing portion 1a disposed in the boundary position K, the cutting process for the collective board 1 is performed. Then, a divided respective circuit board 2 is formed so as to finish the manufacturing. Accordingly, as shown in FIG. 6, it is possible to obtain a circuit module having a desirable electric circuit.

In the embodiment, in a state with the collective board 1, the second bonding process for the electronic part 10 is described. For example, when the circuit board 2 is large and uses various electronic parts 10, the collective board 1 is cut so as to form the divided collective board 1 on the circuit board 2. Accordingly, the second bonding process for the electronic part 10 may be performed.

The method of manufacturing the circuit module of the invention, as shown in FIG. 6, the extending pattern 5 extends to the end portion of two different side of the circuit board 2 in a state where the extending pattern 5 is connected to the first land portion 4a. The bare chip 8 may be performed the burn-in test in a state where the bare chip 8 is attached to the circuit board 2. Accordingly, it is possible to confirm the reliability of the bonding state between the using of the collective board 1 having the plurality of circuit board 2 and the first land portion 4a of bare chip 8.

What is claimed is:

1. A method of manufacturing a circuit module including a plurality of circuit boards having circuit patterns for forming a plurality of circuit modules and a collective board having extensions connected between the plurality of circuit boards to each other, wherein the circuit board includes a plurality of extending patterns which are connected to the circuit patterns, which include a plurality of first land portions for connection to a bare chip and a plurality of second land portions for connection to an electronic part other than the bare chip, and which extend to boundary positions between the circuit boards and the extensions in a state where the plurality of extending patterns are connected to the first land portions, and the extensions include a plurality of extracting patterns connected to the extending patterns, the method comprising:
a first bonding process of connecting the bare chip to the first land portions;
a burn-in test process of electrifying the bare chip using the extending patterns and the extracting patterns at a high temperature so as to determine goodness and badness of the bare chip connected to each circuit boards; and
a second bonding process of bonding the electronic part to the second land portions of the circuit boards having the bare chip with goodness after performing the burn-in test process.

2. The method according to claim 1, wherein a cutting process of cutting the collective board in the boundary positions is performed after performing the second bonding process to the collective board so as to obtain the individual circuit boards.

3. The method according to claim 1, wherein a cutting process of cutting the collective board of the boundary positions so as to obtain the individual circuit boards is performed, and then the second bonding process is performed after performing the burn-in test process.

4. A collective board for a circuit module, comprising:
a plurality of circuit boards having a circuit pattern for forming a circuit module, and
extensions connected between the circuit boards,
wherein the circuit board includes a plurality of extending patterns which are connected to the circuit patterns, which include a plurality of first land portions for connection to a bare chip and a plurality of second land portions for connection to an electronic part other than the bare chip, and which extend to boundary positions between the circuit boards and the extensions in a state where the plurality of extending patterns are connected to the first land portions, and the extensions include a plurality of extracting patterns connected to the extending patterns.

5. The collective board according to claim 4, wherein the extensions include a first connection portion disposed between the adjacent circuit boards and a second connection portion disposed in an outer peripheral portion thereof, and the extracting patterns are provided in the first and second connection portions.

6. The collective board according to claim 5, wherein a plurality of burn-in test electrodes are provided in
end portions of the extracting patterns and the plurality of burn-in test electrodes are concentrated on the second connection portions disposed in one side of the outer peripheral portion.

7. The collective board according to claim 5, wherein a plurality of burn-in test electrodes are provided in end portions of the extracting patterns, convex portions protruding outward are provided in the second connection portions disposed in one side of the outer peripheral portion, and the plurality of burn-in test electrodes are concentrated on the convex portions.

8. A circuit module comprising:
a circuit board having a circuit pattern;
a bare chip mounted on the circuit board; and
an electronic part other than the bare chip mounted on the circuit board,
wherein the circuit pattern includes a plurality of first land portions, a plurality of second land portions so as to connect the electronic part other than the bare chip, and a pattern connected to the first land portions and the second land portions, and in the circuit board, a plurality of extending patterns extending to an end portion of the circuit board in a state where the plurality of extending patterns are connected to the first land portion.

9. The circuit module according to claim 8, wherein the end portions of the extending patterns are disposed in two different sides of the circuit boards.
